(19) United States
(12) Patent Application Publication
(10) Pub. No.: US 2009/0095320 A1
(43) Pub. Date: Apr. 16, 2009

(54) Composition for Removing Photresist Layer and Method for Using it

(75) Inventors: Shumin Wang, Shanghai (CN); Chris Chang Yu, Shanghai (CN)

Correspondence Address: JACOBSON HOLMAN PLLC, 400 SEVENTH STREET N.W., SUITE 600, WASHINGTON, DC, 20004, US

(73) Assignee: ANJI MICROELECTRONICS (SHANGHAI) CO., LTD., Shanghai (CN)

(21) Appl. No.: 11/920,248

(22) PCT Filed: May 12, 2006
(86) PCT No.: PCT/CN2006/000955

§ 371 Date: Nov. 13, 2007

(30) Foreign Application Priority Data
May 13, 2005 (CN) 200510025822.6

(51) Int. Cl. B08B 3/08; G03F 7/42; B08B 3/12; B08B 1/04

(52) U.S. Cl. 134/1.3; 510/176; 134/32; 134/33; 134/6

(57) ABSTRACT

A new composition for removing a photoresist layer and a method for using the same are disclosed. The composition comprises a polar solvent and an oxidant. The composition according to the present invention comprises chemical substances with less toxicity and flammability at lower contents, which makes it more friendly to environment and decreases the expense for disposing the chemical waste. The method for using the composition shortens the time for cleaning and removes the residue more completely, thereby enhancing the electrical conductivity.

### TECHNICAL FIELD

The present invention relates to a composition for removing a photoresist layer in semiconductor manufacturing processes and the method for using the same.

### BACKGROUND ART

In the manufacture of semiconducting elements and devices, the coating, exposing and imaging of a photoresist layer can be used to construct necessary patterns. At the end of patterning (i.e. after the coating, imaging and ion-implantation of the photoresist layer) (as shown in FIG. 1), the remaining photoresist material needs to be removed prior to the next process step. The polymer in the photoresist layer becomes more rigid under the attack of ions in an ion-implantation doping process, so that the photoresist layer is less soluble and thus more difficult to be removed. Heretofore, a two-step process involving plasma etching and wet etching has been used in semiconductor manufacturing to remove such a photoresist layer/film, wherein a larger part of the photoresist layer is removed by plasma etching in the first step, and a cleaning composition with high content of, and usually toxic chemical constituents is used in the second step. The cleaning process is carried out in a long time, and often needs to be assisted by elevating the temperature. In addition, the two-step process needs different equipments, resulting in relatively high cost. Furthermore, the process of prior art sometimes may leave some residue instead of cleaning the whole photoresist layer.

In prior art, some chemical constituents, e.g. organic solvents, polar solvents and fluorine compounds, are typically used at relatively high concentrations, such as those described in U.S. Pat. No. 6,777,380 to Small EKC, U.S. Pat. No. 6,274,537 to Park Samsung and US20040106531 to Kanno et al.

All in all, the process suffers from high cost, low output and other problems associated with environment and photoresist which can not be cleaned completely. Thus, considering the above problems, there is an urgent need for a new process for cleaning a photoresist layer.

### SUMMARY OF INVENTION

The object according to the present invention is to solve the forementioned problems by providing a novel composition useful for cleaning a photoresist layer, which comprises a polar solvent, wherein it also comprises an oxidant. The photoresist layer typically comprises an organic compound and/or a polymer. The polar solvent can soften or dissolve the photoresist layer or the organic compound and polymer in the photoresist layer, while the oxidant can oxidize the organic compound and polymer, and break up their molecular structures, so as to effect the removal of the photoresist layer.

The composition can also comprise a surfactant, an inhibitor and/or a carrier. Said inhibitor can mitigate or prevent degradation, corrosion and point corrosion of the underlay substrate due to chemical or mechanical processes. In an ion-implantation process, a typical substrate is a silicon substrate, on which sometimes is deposited a thin oxidized layer. A polishing pad, which may be any plastic sheet having a surface that is flat or otherwise treated/channeled, is used to ensure the dispersion of adequate rinsing solution on the polishing pad. The underlay substrate includes but is not limited to silicon, silicon dioxide, ion-doped silicon dioxide, materials having low dielectric constant k and metal substrates such as aluminum or copper. Preferably, said carrier is water.

The mass percent concentrations, based on the total mass of the composition, are 5-80% for the polar solvent, 0.01-8% for the oxidant, 0.001-5% for the surfactant, 0.005-10% for the inhibitor and the balance for the carrier.

Said oxidant is one or more of organic or inorganic oxidants, among which hydrogen peroxide, peroxyacetic acid, peroxyboric acid, sodium peroxide, ammonium peroxydisulfate, potassium hypermanganate, nitric acid and/or nitrates are preferred.

Said polar solvent is preferably an amine, an alcohol, an alcohol amine, an ether and/or a ketone, wherein said alcohol is preferably an alkanol or a polyol.

Said inhibitor is a mono- or poly-basic carboxylic acid and its salt, a water-soluble charged ionic organic material, a water-soluble charged ionic polymer and/or a water-soluble polymer containing nitrogen. A preferred nitrogen containing polymer is a polyamine, e.g. vinyl amine and its salts, an amide, e.g. polyamide-imide or polyamide, and a polyamine and/or an azole. Said azole is preferably benzotriazole, benzoimidazole, triazole and/or their derivatives.

The composition may also comprise one or more of a complexing agent, a dispersing agent, a catalyst and a pH mediator.

Another object according to the present invention is to provide a method for using said composition, which comprises soaking a substrate to be cleaned in the composition according to the present invention until the photoresist layer is removed completely.

A preferred method is one wherein soaking is carried out at room temperature or under heating where the elevated temperature is not higher than the boiling point of the composition.

Another preferred method is one wherein the substrate is mechanically oscillated while being soaked.

Another preferred method is one wherein ultrasonic energy is used to treat said composition.

Another object according to the present invention is to provide another method for using said composition, which comprises soaking a rotating substrate in the composition according to the present invention, or applying the composition according to the present invention on the rotating substrate.

Another object according to the present invention is to provide another method for using said composition, which comprises the following steps: 1) placing a polishing pad on a polishing platform, and placing a wafer in a wafer holder, so that the wafer contacts the polishing pad under an appropriate pressure applied; 2) applying the composition according to the present invention on the polishing pad and the wafer in contact with the polishing pad, and rotating the polishing pad and/or the wafer, so that the polishing pad abrades the surface of the wafer until the photoresist layer is removed completely.

The polished wafer can be taken out from the holder to be washed. The wafer may be washed with deionized water only. Alternatively, the deionized water may comprise an additive to effect better removal of the remaining composition on the wafer as well as the substance generated by the polishing. Preferably, the wafer is washed while it is being brushed. The washing of the wafer may mean the use of the same or different polishing pads on the same or different polishing platforms.

The beneficial effects according to the present invention comprise: 1) said composition comprises chemical substances with less toxicity and less flammability at lower contents, which makes it more friendly to environment and decreases the expense for disposing the chemical waste; 2) the method for using said composition shortens the time for cleaning, resulting the increase of output; 3) the residue is removed more completely, thereby enhancing the electrical conductivity; 4) the cost may be reduced by using the method according to the present invention.

### BRIEF DESCRIPTION OF THE DRAWINGS

FIG. 1 is the flow diagram of coating, exposing, imaging and plasma etching of a photoresist layer according to prior art.

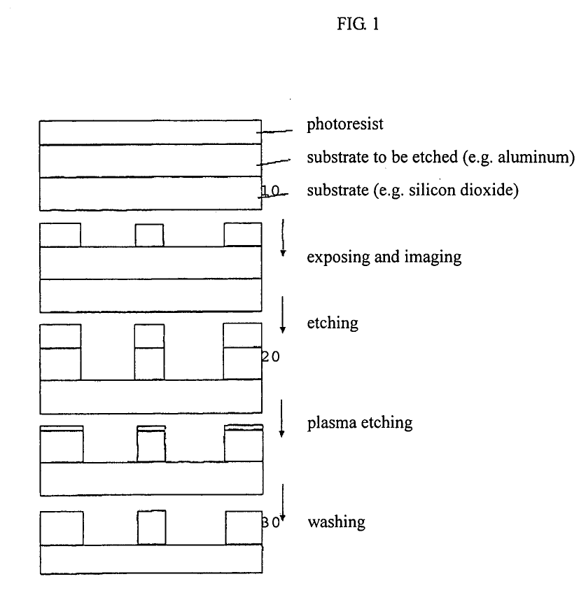

### BEST MODE FOR CARRYING OUT THE INVENTION

Following are preferred examples according to the present invention, provided as a detailed illustration of the technical designs according to the present invention.

### Example 1

Constituents of the composition: 20 g ammonium peroxydisulfate, 500 g ethylene glycol and 480 g deionized water.

The substrate to be cleaned was placed in a coverable solution tank into which said composition was added. The composition was heated to 45° C., and the substrate was soaked for 5 min. Then, the substrate was taken out and washed with deionized water.

### Example 2

Constituents of the composition: 40 g hydrogen peroxide, 500 g N-methyl-2-pyrrolidone and 460 g deionized water.

The substrate to be cleaned was placed in a coverable solution tank into which said composition was added. The composition was heated to 45° C., and the substrate was soaked for 5 min. Then, the substrate was taken out and washed with deionized water.

### Example 3

Constituents of the composition: 20 g ammonium peroxydisulfate, 500 g ethylene glycol, 0.1 g non-ionic surfactant and 479.9 g deionized water.

The substrate to be cleaned was placed in a coverable solution tank into which said composition was added. The composition was heated to 45° C., and the substrate was soaked for 5 min. Then, the substrate was taken out and washed with deionized water.

### Example 4

Constituents of the composition: 40 g hydrogen peroxide, 500 g N-methyl-2-pyrrolidone, 0.1 g non-ionic surfactant, 1 g benzotriazole and 458.9 g deionized water.

The substrate to be cleaned was placed in a coverable solution tank into which said composition was added. The composition was heated to 45° C., and the substrate was soaked for 5 min. Then, the substrate was taken out and washed with deionized water.

### Example 5

Constituents of the composition: 0.1 g peroxyacetic acid, 800 g N-methyl-2-pyrrolidone, 0.01 g non-ionic surfactant, 0.05 g benzoimidazole and 199.84 g deionized water.

The substrate to be cleaned was placed in said composition, and the composition was subject to ultrasonic wave at an oscillating frequency of 40 MHz. Five minutes later, the substrate was taken out and washed with deionized water.

### Example 6

Constituents of the composition: 80 g potassium hypermanganate, 50 g acetone, 5 g non-ionic surfactant, 50 g triazole and 815 g deionized water.

The substrate to be cleaned was placed on a rotating disk at 375 rpm, and the rotating substrate was soaked in said composition, or said composition was applied on the rotating substrate, until the photoresist layer was removed completely.

### Example 7

Constituents of the composition: 80 g potassium hypermanganate, 50 g acetone, 50 g non-ionic surfactant, 1000 g triazole and 720 g deionized water.

A polwashing pad was placed on a polishing platform, and a wafer was placed in a wafer holder. The wafer got into contact with the polishing pad under an applied pressure of 3 Psi. Said composition was applied on the polishing pad and the wafer in contact with the polishing pad. The polishing pad was rotating at a speed of 75 rpm while the wafer was rotating at a speed of 55 rpm, so that the polishing pad abraded the surface of the wafer until the photoresist layer was removed completely.

1. A composition useful for removing a photoresist layer, comprising a polar solvent, wherein it further comprises an oxidant.

2. The composition according to claim 1, wherein it further comprises a surfactant, an inhibitor and/or a carrier.

3. The composition according to claim 2, wherein the mass percent concentrations are 5-80% for the polar solvent, 0.01-8% for the oxidant, 0.001-5% for the surfactant, 0.005-10% for the inhibitor and the balance for the carrier, based on the total mass of the composition.

4. The composition according to claim 1, wherein the oxidant is one or more of organic or inorganic oxidants.

5. The composition according to claim 4, wherein the oxidant is hydrogen peroxide, peroxyacetic acid, peroxyboric acid, sodium peroxide, ammonium peroxydisulfate, potassium hypermanganate, nitric acid and/or nitrates.

6. The composition according to claim 1, wherein the polar solvent is an amine, an alcohol, an alcohol amine, an ether and/or a ketone.

7. The composition according to claim 1, wherein said alcohol is an alkanol or a polyol.

8. The composition according to claim 2, wherein the inhibitor is a mono- or poly-basic carboxylic acid and its salt, a water-soluble charged ionic organic material, a water-soluble charged ionic polymer and/or a water-soluble polymer containing nitrogen.

9. The composition according to claim 8, wherein said nitrogen containing polymer is a polyamine, an amide, a polyamine and/or an azole.

10. The composition according to claim 9, wherein said azole is benzotriazole, benzoimidazole, triazole and/or their derivatives.

11. The composition according to any one of claim 1-10, wherein the composition further comprises one or more of a complexing agent, a dispersing agent, a catalyst and a pH mediator.

12. A method for using the composition according to any one of claim 1-10, wherein a substrate to be cleaned is soaked in the composition according to any one of claim 1-10 until the photoresist layer is removed completely.

13. The method according to claim 12, wherein soaking is carried out at room temperature or under heating where the elevated temperature is not higher than the boiling point of the composition.

14. The method according to claim 12, wherein the substrate is mechanically oscillated while being soaked.

15. The method according to claim 12, wherein ultrasonic energy is used to treat said composition.

16. A method for using the composition according to any one of claim 1-10, wherein a rotating substrate is soaked in the composition according to any one of claim 1-10, or the composition according to any one of claim 1-10 is applied on the rotating substrate.

17. A method for using the composition according to any one of claim 1-10, comprising the following steps: 1) placing a polishing pad on a polishing platform, and placing a wafer in a wafer holder, so that the wafer contacts the polishing pad under an appropriate pressure applied; 2) applying the composition according to any one of claim 1-10 on the polishing pad and the wafer in contact with the polishing pad, and rotating the polishing pad and/or the wafer, so that the polishing pad abrades the surface of the wafer until the photoresist layer is removed completely.
